(19) United States
(12) Patent Application Publication
(10) Pub. No.: US 2026/0101561 A1
(43) Pub. Date: Apr. 9, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiroki NEMOTO, Meguro Tokyo (JP); Tomoaki INOKUCHI, Yokohama Kanagawa (JP); Tatsuya NISHIWAKI, Yokohama Kanagawa (JP); Hiroki SAKATA, Kawasaki Kanagawa (JP); Yusuke KOBAYASHI, Yokohama Kanagawa (JP); Shotaro BABA, Kawasaki Kanagawa (JP); Hiro GANGI, Marugame Kagawa (JP); Taichi FUKUDA, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/248,561

(22) Filed: Jun. 25, 2025

(30) Foreign Application Priority Data
Oct. 3, 2024 (JP) 2024-174501

(51) Int. Cl. H10D 64/23; H10D 30/66; H10D 64/00; H10D 64/27; H10D 84/83

(52) U.S. Cl. CPC H10D 64/2527; H10D 30/668; H10D 64/117; H10D 64/518; H10D 84/839; H10D 64/513

(57) ABSTRACT

According to one embodiment, a semiconductor device includes first to third electrodes, a first conductive member, a semiconductor member, and a first insulating member. The first conductive member is electrically connected to the second electrode. The first conductive member includes a first conductive portion and a second conductive portion. A first material of the first conductive region of first conductive portion is different from a second material of the second conductive region of the second conductive portion. The semiconductor member is provided between the first electrode and the second electrode. The semiconductor member includes a first semiconductor layer of a first conductivity type and a second semiconductor layer of the first conductivity type. The first semiconductor layer includes a first partial region and a second partial region.

### CROSS-REFERENCE TO RELATED APPLICATIONS

This application is based upon and claims the benefit of priority from Japanese Patent Application No. 2024-174501, filed on Oct. 3, 2024; the entire contents of which are incorporated herein by reference.

### FIELD

Embodiments described herein relate generally to a semiconductor device.

### BACKGROUND

For example, it is desired to improve the characteristics of semiconductor devices.

### BRIEF DESCRIPTION OF THE DRAWINGS

FIGS. 1A and 1B are schematic cross-sectional views illustrating a semiconductor device according to a first embodiment;

FIG. 2 is a schematic plan view illustrating the semiconductor device according to the first embodiment;

FIGS. 3A and 3B are schematic cross-sectional views illustrating the semiconductor device according to the first embodiment;

FIGS. 4A and 4B are schematic cross-sectional views illustrating a semiconductor device according to the first embodiment; and

FIG. 5 is a schematic cross-sectional view illustrating the semiconductor device according to the first embodiment.

### DETAILED DESCRIPTION

According to one embodiment, a semiconductor device includes a first electrode, a second electrode, a third electrode, a first conductive member, a semiconductor member, and a first insulating member. A direction from the first electrode to the second electrode is along a first direction. The first conductive member is electrically connected to the second electrode. A second direction from the third electrode to at least a part of the first conductive member crosses the first direction. The first conductive member extends along a third direction crossing a plane including the first direction and the second direction. The first conductive member includes a first conductive portion and a second conductive portion. A direction from the first conductive portion to the second conductive portion is along the third direction. The first conductive portion includes a first conductive region. The second conductive portion includes a second conductive region. A first material of the first conductive region is different from a second material of the second conductive region. The semiconductor member is provided between the first electrode and the second electrode. The semiconductor member includes a first semiconductor layer of a first conductivity type and a second semiconductor layer of the first conductivity type. The first semiconductor layer includes a first partial region and a second partial region. The first partial region is between the first electrode and the third electrode in the first direction. The second partial region is between the first electrode and the first conductive member in the first direction. The second partial region includes a first semiconductor region and a second semiconductor region. The first semiconductor region is in contact with the first conductive region. The second semiconductor region is in contact with the second conductive region. At least a part of the second semiconductor layer is between the third electrode and the first conductive portion in the second direction. The second semiconductor layer is not provided between the third electrode and the second conductive portion in the second direction. A second impurity concentration of the first conductivity type in the second semiconductor layer is higher than a first impurity concentration of the first conductivity type in the first semiconductor layer. The first insulating member is provided between the third electrode and the semiconductor member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

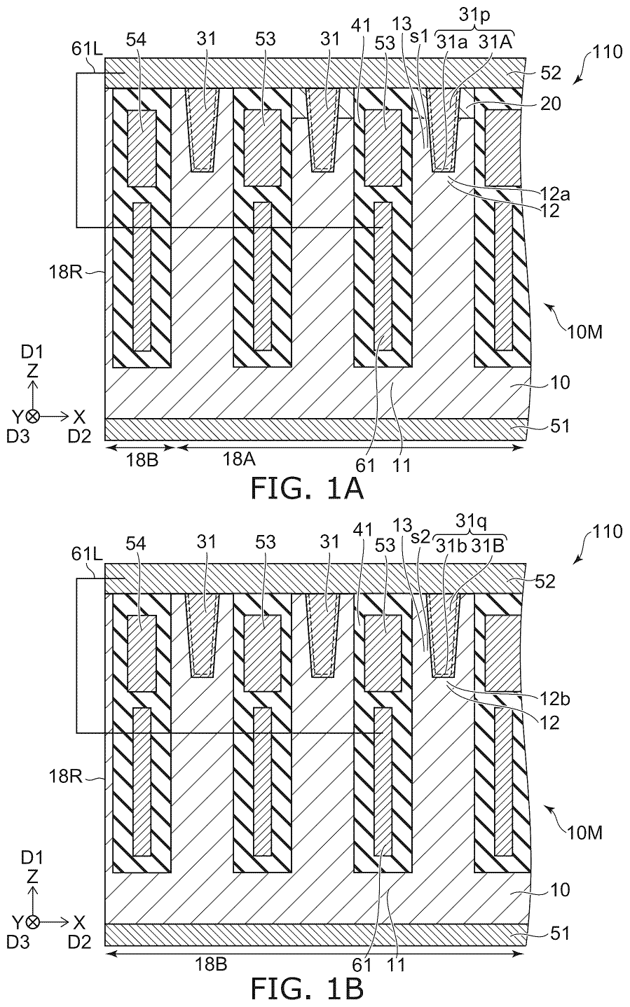

FIGS. 1A and 1B are schematic cross-sectional views illustrating a semiconductor device according to a first embodiment.

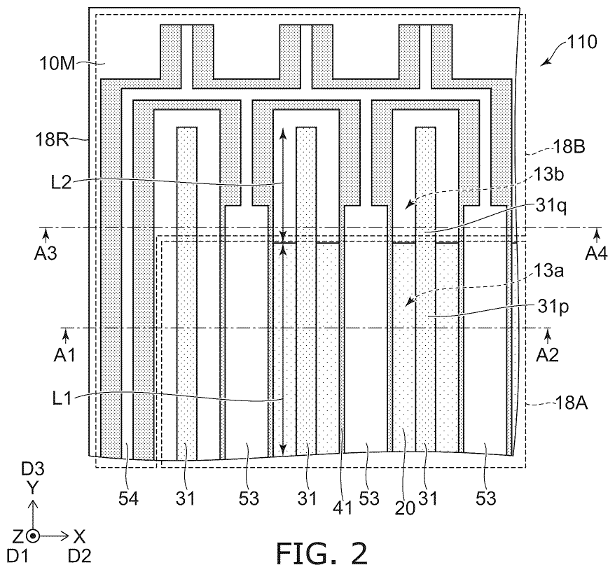

FIG. 2 is a schematic plan view illustrating the semiconductor device according to the first embodiment.

FIG. 1A is a cross-sectional view taken along the line A1-A2 in FIG. 2. FIG. 1B is a cross-sectional view taken along the line A3-A4 in FIG. 2.

As shown in FIGS. 1A, 1B and 2, a semiconductor device 110 includes a first electrode 51, a second electrode 52, a third electrode 53, a first conductive member 31, a semiconductor member 10M, and a first insulating member 41. A direction from the first electrode 51 to the second electrode 52 is along a first direction D1.

The first direction D1 is defined as a Z-axis direction. One direction perpendicular to the Z-axis direction is defined as an X-axis direction. A direction perpendicular to the Z-axis direction and the X-axis direction is defined as a Y-axis direction.

The first conductive member 31 is electrically connected to the second electrode 52. A second direction D2 from the third electrode 53 to at least a part of the first conductive member 31 crosse the first direction D1. The second direction D2 may be, for example, the X-axis direction.

As shown in FIG. 2, the first conductive member 31 extends along a third direction D3. The third direction D3 crosses a plane including the first direction D1 and the second direction D2. The third direction D3 may be, for example, the Y-axis direction.

As shown in FIG. 2, the first conductive member 31 includes a first conductive portion 31p and a second conductive portion 31q. A direction from the first conductive portion 31p to the second conductive portion 31q is along the third direction D3. The third electrode 53 may extend along the third direction D3.

A plurality of third electrodes 53 may be provided. A direction from one of the plurality of third electrodes 53 to another one of the plurality of third electrodes 53 is along the second direction D2. A plurality of first conductive members 31 may be provided. A direction from one of the plurality of first conductive members 31 to another one of the plurality of first conductive members 31 is along the second direction D2. Below, one of the plurality of third electrodes 53 and one of the plurality of first conductive members 31 will be described.

As shown in FIG. 1A, the first conductive portion 31p includes a first conductive region 31a. As shown in FIG. 1B, the second conductive portion 31q includes a second conductive region 31b. A first material of the first conductive region 31a is different from a second material of the second conductive region 31b. Examples of these materials will be described later.

The semiconductor member 10M is provided between the first electrode 51 and the second electrode 52 in the first direction D1. The semiconductor member 10M includes a first semiconductor layer 10 of a first conductivity type and a second semiconductor layer 20 of the first conductivity type. The first conductivity type is, for example, n-type. The first conductivity type may also be p-type. In the following, the first conductivity type is defined as n-type.

The first semiconductor layer 10 includes a first partial region 11 and a second partial region 12. The first partial region 11 is located between the first electrode 51 and the third electrode 53 in the first direction D1. The second partial region 12 is located between the first electrode 51 and the first conductive member 31 in the first direction D1.

The second partial region 12 includes a first semiconductor region 12a and a second semiconductor region 12b. The first semiconductor region 12a contacts the first conductive region 31a. The second semiconductor region 12b contacts the second conductive region 31b.

As shown in FIG. 1A, at least a part of the second semiconductor layer 20 is between the third electrode 53 and the first conductive portion 31p in the second direction D2. As shown in FIG. 1B, the second semiconductor layer 20 is not provided between the third electrode 53 and the second conductive portion 31q in the second direction D2. A second impurity concentration of the first conductivity type in the second semiconductor layer 20 is higher than a first impurity concentration of the first conductivity type in the first semiconductor layer 10.

The first insulating member 41 is provided between the third electrode 53 and the semiconductor member 10M. The first insulating member 41 electrically insulates the third electrode 53 from the semiconductor member 10M. A part of the first insulating member 41 may be provided between the third electrode 53 and the second electrode 52. The first insulating member 41 electrically insulates the third electrode 53 from the second electrode 52.

Electric current flowing between the first electrode 51 and the second electrode 52 can be controlled by a potential of the third electrode 53. The potential of the third electrode 53 may be a potential based on a potential of the second electrode 52. The first electrode 51 functions as, for example, a drain electrode. The second electrode 52 functions as, for example, a source electrode. The third electrode 53 functions as, for example, a gate electrode. The semiconductor device 110 is, for example, a transistor.

The electric current flowing between the first electrode 51 and the second electrode 52 may flow via the first conductive member 31. For example, the thickness of the barrier between the semiconductor member 10M and the first conductive member 31 can be controlled by the potential of the third electrode 53. Control of the current by the potential of the third electrode 53 may be based on control of the barrier thickness.

As described above, there are provided a region where the second semiconductor layer 20 is provided and a region where the second semiconductor layer 20 is not provided. The above-mentioned current control is performed in the region where the second semiconductor layer 20 is provided. The region where the second semiconductor layer 20 is provided corresponds to, for example, a switching region. The region where the second semiconductor layer 20 is not provided corresponds to, for example, a non-switching region.

As described above, the first semiconductor region 12a and the first conductive region 31a correspond to the switching region. The second semiconductor region 12b and the second conductive region 31b correspond to the non-switching region. In the embodiment, the first material of the first conductive region 31a corresponding to the non-switching region is different from the second material of the second conductive region 31b corresponding to the switching region. This allows for good characteristics to be obtained.

In the embodiment, the first material corresponding to the switching region is different from the second material corresponding to the non-switching region. For example, a material that provides appropriate characteristics when switching is in on-state can be applied to the first material. For example, a material that provides appropriate characteristics when switching is in off-state can be applied to the second material. According to the embodiment, a semiconductor device with improved characteristics can be provided.

For example, good on-characteristics can be obtained. For example, good off-characteristics can be obtained. For example, low on-resistance can be obtained. For example, leakage current can be suppressed.

In one example, the second barrier height of the second material is higher than the first barrier height of the first material. For example, the second work function of the second material is higher than the first work function of the first material. Such a second material can reduce, for example, leakage current.

In one example, the second conductive region 31b includes a first element including at least one selected from the group consisting of B, In, Ga, and Al. The first conductive region 31a does not include the first element. Or, a second concentration of the first element in the second conductive region 31b is higher than a first concentration of the first element in the first conductive region 31a. Such a second conductive region 31b (second material) can provide a low leakage current. Such a second conductive region 31b (second material) can provide, for example, a high barrier height (for example, a high work function).

In one example, the second conductive region 31b includes oxygen. The first conductive region 31a does not include oxygen. Or, a second oxygen concentration in the second conductive region 31b is higher than a first oxygen concentration in the first conductive region 31a. A low leakage current is obtained by such a second conductive region 31b (second material). For example, a high barrier height (for example, a high work function) is obtained by such a second conductive region 31b (second material).

In one example, the second conductive region 31b may include a first material. The first material includes, for example, at least one of Al, Ti, Zr, Mg, and Hf, and oxygen. The first conductive region 31a does not include the first material. Or, the second concentration of the first material in the second conductive region 31b is higher than the first concentration of the first material in the first conductive region 31a. A low leakage current can be obtained by using such a second conductive region 31b (second material). For example, a high barrier height (for example, a high work function) can be obtained by using such a second conductive region 31b (second material).

The second conductive region 31b may include, for example, a stacked film.

As shown in FIG. 1A, the first semiconductor region 12a contacts the first conductive region 31a. The first conductive region 31a may be a part of the first conductive portion 31p. The first conductive portion 31p may further include a first intermediate region 31A. The first conductive region 31a is provided between the semiconductor member 10M and the first intermediate region 31A. The first intermediate region 31A is provided between the first conductive region 31a and the second electrode 52. A material of the first intermediate region 31A may be the same as the material of the first conductive region 31a. The first intermediate region 31A may be continuous with the first conductive region 31a. The boundary between these regions may be unclear.

As shown in FIG. 1B, the second semiconductor region 12b contacts the second conductive region 31b. The second conductive region 31b may be a part of the second conductive portion 31q. The second conductive portion 31q may further include a second intermediate region 31B. The second conductive region 31b is provided between the semiconductor member 10M and the second intermediate region 31B. The second intermediate region 31B is provided between the second conductive region 31b and the second electrode 52. A second intermediate region material of the second intermediate region 31B may be different from the second material of the second conductive region 31b. The second intermediate region material of the second intermediate region 31B may be substantially the same as the first intermediate region material of the first intermediate region 31A.

As described above, the first material of the first conductive region 31a is different from the second material of the second conductive region 31b. When comparing these materials, materials at similar positions are compared. For example, in the first conductive region 31a, the material at a first position with a first distance from the semiconductor member 10M is considered to be the first material. For example, in the second conductive region 31b, the material at a second position with the first distance from the semiconductor member 10M is considered to be the second material.

For example, the concentration of the first element may change in a direction crossing the interface between the semiconductor member 10M and the first conductive member 31. In this case, the difference in material can be understood by comparing the concentrations at the same distance (first distance) from the interface between the semiconductor member 10M and the first conductive member 31. Practically, the first distance may be not less than 5 nm and not more than 10 nm.

At least one of the first intermediate region 31A or the second intermediate region 31B may include, for example, at least one selected from the group consisting of Ti, Mo, W, Cr, Co, Ni, Pt, and Ir. For example, the first conductive portion 31p and the second intermediate region 31B satisfy a first condition, a second condition, or a third condition. In the first condition, the first conductive portion 31p includes W, and the second intermediate region 31B includes at least one selected from the group consisting of Pt and Ir. In the second condition, the first conductive portion 31p includes Ni, and the second intermediate region 31B includes at least one selected from the group consisting of Pt and Ir. In the third condition, the first conductive portion 31p includes Pt, and the second intermediate region 31B includes Ir.

In the embodiment, the semiconductor member 10M may include silicon. The semiconductor member 10M may include a compound semiconductor. The compound semiconductor may include at least one selected from the group consisting of SiC, GaN, GaO, and GaAs.

In the embodiment, the first conductive region 31a may form a Schottky junction with the first semiconductor region 12a. The second conductive region 31b may form a Schottky junction with the second semiconductor region 12b.

As shown in FIG. 2, the semiconductor member 10M includes a cell region 18A, a terminal region 18B, and an outer edge 18R. The terminal region 18B is located between the cell region 18A and the outer edge 18R in a direction crossing the first direction D1. The first semiconductor region 12a is included in the cell region 18A. The second semiconductor region 12b is included in the terminal region 18B. The cell region 18A corresponds to a switching region. The terminal region 18B corresponds to a non-switching region.

As shown in FIG. 1A and FIG. 1B, the semiconductor device 110 may further include a first conductive part 61. The first conductive part 61 is electrically connected to the second electrode 52. For example, the first conductive part 61 may be electrically connected to the second electrode 52 by a wiring 61L or the like at a cross-sectional position different from those shown in these figures.

A position (first conductive part position) of at least a part of the first conductive part 61 in the first direction D1 is between a position (first electrode position) of the first electrode 51 in the first direction D1 and a position (third electrode position) of the third electrode 53 in the first direction D1. A part of the first insulating member 41 is between the first conductive part 61 and the semiconductor member 10M, and between the first conductive part 61 and the third electrode 53.

In this example, the first conductive part 61 is located between the first partial region 11 and the third electrode 53 in the first direction D1. A length (width) of the third electrode 53 in the second direction D2 may be longer than a length (width) of the first conductive part 61 in the second direction D2.

The second conductive region 31b may be formed, for example, by selectively introducing an element that will become the above-mentioned first element (or first substance) into a trench formed in the semiconductor member 10M, and then filling the remaining space in the trench with a metal or the like. The introduction of the element may include, for example, film formation. The introduction of the element may include, for example, ion implantation.

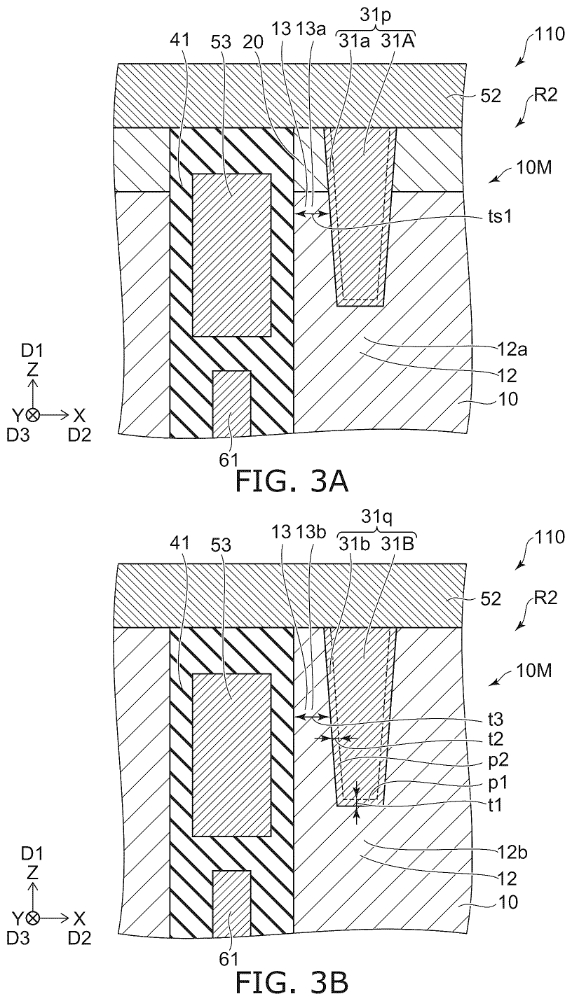

FIGS. 3A and 3B are schematic cross-sectional views illustrating the semiconductor device according to the first embodiment.

FIG. 3A is an enlarged view of a part of FIG. 1A. FIG. 3B is an enlarged view of a part of FIG. 1B.

As shown in FIG. 3B, the second conductive region 31b may include a first portion p1. The first portion p1 is located between the second semiconductor region 12b and the second intermediate region 31B in the first direction D1. A first thickness t1 of the first portion p1 may be, for example, not less than 1 nm and not more than 50 nm. By the first thickness t1 being 1 nm or more, for example, the leakage current can be stably reduced. By the first thickness t1 being 50 nm or less, for example, deterioration of characteristics can be suppressed.

As shown in FIGS. 3A and 3B, the first semiconductor layer 10 may further include a third partial region 13. The third partial region 13 includes a first side region 13a (FIG. 3A) and a second side region 13b (FIG. 3B). As shown in FIG. 3A, at least a part of the first side region 13a is located between at least a part of the third electrode 53 and the first conductive portion 31p in the second direction D2. As shown in FIG. 3B, at least a part of the second side region 13b is located between at least a part of the third electrode 53 and the second conductive portion 31q in the second direction D2.

The thickness of the first side region 13a in the second direction D2 (first side region thickness ts1) may be, for example, not less than 10 nm and not more than 200 nm. The first side region thickness ts1 may be not less than 10 nm and not more than 80 nm. By the first side region thickness ts1 being 10 nm or more, for example, stable characteristics are easily obtained. By the first side region thickness ts1 being 80 nm or less, for example, an appropriate threshold voltage is easily obtained.

As described above, at least a part of the second side region 13b is located between at least a part of the third electrode 53 and the second conductive portion 31q in the second direction D2. The second conductive region 31b of the second conductive portion 31q further includes a second portion p2. The second portion p2 is provided between the second side region 13b and the second intermediate region 31B in the second direction D2.

A second thickness t2 of the second portion p2 in the second direction D2 may be, for example, not less than 1 nm and not more than 50 nm. By the second thickness t2 being 1 nm or more, for example, it is possible to stably reduce the leakage current. By the second thickness t2 being 50 nm or less, for example, it is easy to obtain the second portion p2 with uniform characteristics.

As shown in FIG. 2, a length of the first conductive portion 31p in the third direction D3 is defined as a first length L1. A length of the second conductive portion 31q in the third direction D3 is defined as a second length L2. In the embodiment, the first length L1 is longer than the second length L2. For example, the cell region 18A being wide is obtained. Efficient switching characteristics are obtained.

As shown in FIGS. 1A, 1B and 2, the semiconductor device 110 may further include a fourth electrode 54. The fourth electrode 54 may be electrically connected to the third electrode 53. A direction from a part of the terminal region 18B to the fourth electrode 54 is along the first direction D1. The direction from the fourth electrode 54 to the third electrode 53 is along the second direction D2.

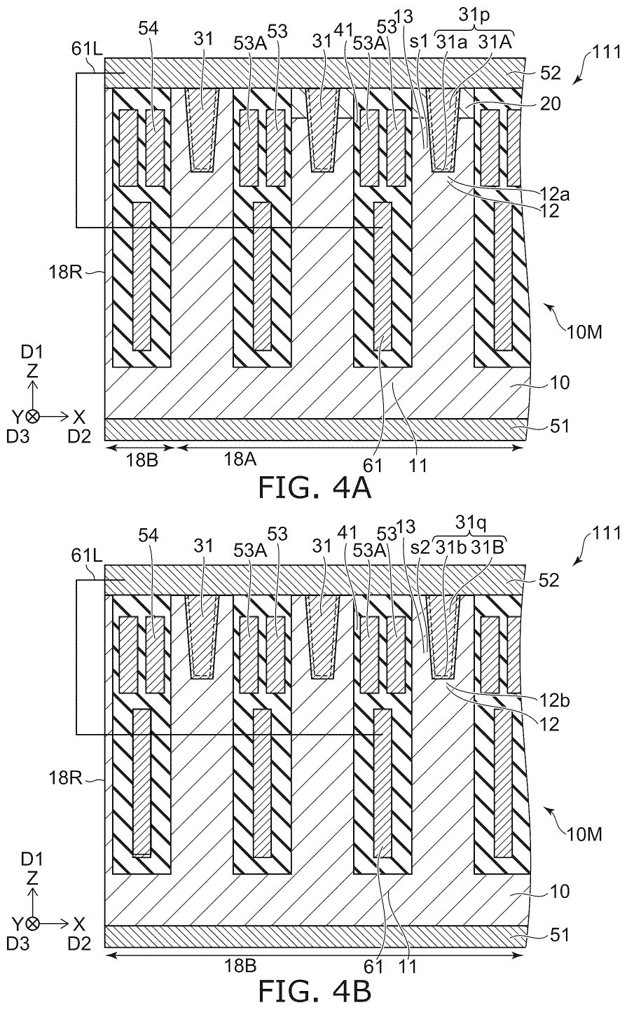

FIGS. 4A and 4B are schematic cross-sectional views illustrating a semiconductor device according to the first embodiment.

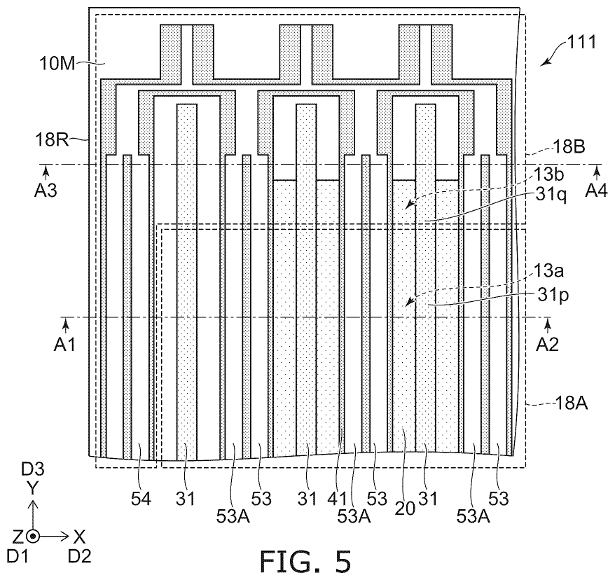

FIG. 5 is a schematic cross-sectional view illustrating the semiconductor device according to the first embodiment.

FIG. 4A is a cross-sectional view corresponding to the line A1-A2 in FIG. 5. FIG. 4B is a cross-sectional view corresponding to the line A3-A4 in FIG. 5.

As shown in FIGS. 4A, 4B, and 5, a semiconductor device 111 according to the embodiment further includes a third other electrode 53A. Except for this, the configuration of the semiconductor device 111 may be the same as the configuration of the semiconductor device 110.

The third other electrode 53A extends along the third electrode 53. The third other electrode 53A is electrically connected to the third electrode 53. In the second direction D2, the third electrode 53 is located between the third other electrode 53A and the first conductive member 31. A part of the first insulating member 41 is located between the third other electrode 53A and the third electrode 53.

In the semiconductor device 111 as well, the first material of the first conductive region 31a is different from the second material of the second conductive region 31b. This provides a semiconductor device with improved characteristics. For example, the leakage current can be reduced.

In the embodiment, at least one of the first electrode 51 or the second electrode 52 may include a metal. The metal may include at least one selected from the group consisting of Al, Ti, Ni, Au, Ag, and Cu. At least one of the third electrode 53 or the fourth electrode 54 may include polysilicon.

In the embodiment, information on the shapes of the semiconductor member, the electrodes, and the conductive member is obtained, for example, from electron microscope images. Information on the composition and element concentration is obtained, for example, from EDX (Energy Dispersive X-ray Spectroscopy) or SIMS (Secondary Ion Mass Spectrometry).

The embodiments may include the following Technical proposals:

### Technical Proposal 1

A semiconductor device, comprising:
a first electrode;
a second electrode, a direction from the first electrode to the second electrode being along a first direction:
a third electrode;
a first conductive member electrically connected to the second electrode, a second direction from the third electrode to at least a part of the first conductive member crossing the first direction, the first conductive member extending along a third direction crossing a plane including the first direction and the second direction, the first conductive member including a first conductive portion and a second conductive portion, a direction from the first conductive portion to the second conductive portion being along the third direction, the first conductive portion including a first conductive region, the second conductive portion including a second conductive region, a first material of the first conductive region being different from a second material of the second conductive region;
a semiconductor member provided between the first electrode and the second electrode, the semiconductor member including a first semiconductor layer of a first conductivity type and a second semiconductor layer of the first conductivity type, the first semiconductor layer including a first partial region and a second partial region, the first partial region being between the first electrode and the third electrode in the first direction, the second partial region being between the first electrode and the first conductive member in the first direction, the second partial region including a first semiconductor region and a second semiconductor region, the first semiconductor region being in contact with the first conductive region, the second semiconductor region being in contact with the second conductive region, at least a part of the second semiconductor layer being between the third electrode and the first conductive portion in the second direction, the second semiconductor layer being not provided between the third electrode and the second conductive portion in the second direction, a second impurity concentration of the first conductivity type in the second semiconductor layer being higher than a first impurity concentration of the first conductivity type in the first semiconductor layer; and
a first insulating member provided between the third electrode and the semiconductor member.

### Technical Proposal 2

The semiconductor device according to Technical proposal 1, wherein
the semiconductor member includes a cell region, a terminal region, and an outer edge,
the terminal region is between the cell region and the outer edge in a direction crossing the first direction,
the first semiconductor region is included in the cell region, and
the second semiconductor region is included in the terminal region.

### Technical Proposal 3

The semiconductor device according to Technical proposal 1 or 2, wherein
the second conductive region includes a first element including at least one selected from the group consisting of B, In, Ga, and Al,
the first conductive region does not include the first element, or a second concentration of the first element in the second conductive region is higher than a first concentration of the first element in the first conductive region.

### Technical Proposal 4

The semiconductor device according to Technical proposal 1 or 2, wherein
the second conductive region includes oxygen, and
the first conductive region does not include oxygen, or a second oxygen concentration in the second conductive region is higher than a first oxygen concentration in the first conductive region.

### Technical Proposal 5

The semiconductor device according to Technical proposal 1 or 2, wherein
a second barrier height of the second material is higher than a first barrier height of the first material.

### Technical Proposal 6

The semiconductor device according to any one of Technical proposals 1-5, wherein
the first conductive region forms a Schottky junction with the first semiconductor region.

### Technical Proposal 7

The semiconductor device according to any one of Technical proposals 1-6, wherein
the semiconductor member includes silicon.

### Technical Proposal 8

The semiconductor device according to any one of Technical proposals 1-7, wherein
the second conductive portion further includes a second intermediate region,
the second conductive region is between the semiconductor member and the second intermediate region, and
a second intermediate region material of the second intermediate region is different from the second material.

### Technical Proposal 9

The semiconductor device according to Technical proposal 8, wherein
the first conductive portion and the second intermediate region satisfy a first condition, a second condition, or a third condition,
in the first condition, the first conductive portion includes W and the second intermediate region includes at least one selected from the group consisting of Pt and Ir,
in the second condition, the first conductive portion includes Ni and the second intermediate region includes at least one selected from the group consisting of Pt and Ir, and
in the third condition, the first conductive portion includes Pt and the second intermediate region includes Ir.

### Technical Proposal 10

The semiconductor device according to Technical proposal 8 or 9, wherein
the second conductive region includes a first portion,
the first portion is between the second semiconductor region and the second intermediate region in the first direction, and
a first thickness of the first portion in the first direction is not less than 1 nm and not more than 50 nm.

### Technical Proposal 11

The semiconductor device according to any one of Technical proposals 8-10, wherein
the first semiconductor layer further includes a third partial region,
the third partial region includes a second side region,
at least a part of the second side region is between at least a part of the third electrode and the second conductive portion in the second direction,
the second conductive region includes a second portion, and
the second portion is between the second side region and
the second intermediate region in the second direction.

### Technical Proposal 12

The semiconductor device according Technical proposal 11, wherein
a second thickness of the second portion in the second direction is not less than 1 nm and not more than 50 nm.

### Technical Proposal 13

The semiconductor device according to any one of Technical proposals 1-7, wherein
the first semiconductor layer further includes a third partial region,
the third partial region includes a first side region and a second side region,
at least a part of the first side region is between at least a part of the third electrode and the first conductive portion in the second direction, and
at least a part of the second side region is between at least a part of the third electrode and the second conductive portion in the second direction.

### Technical Proposal 14

The semiconductor device according to Technical proposal 13, wherein
a first side region thickness of the first side region in the second direction is not less than 10 nm and not more than 200 nm.

### Technical Proposal 15

The semiconductor device according to any one of Technical proposals 1-14, wherein
a first length of the first conductive portion in the third direction is longer than a second length of the second conductive portion in the third direction.

### Technical Proposal 16

The semiconductor device according to any one of Technical proposals 1-15, wherein
the third electrode extends along the third direction.

### Technical Proposal 17

The semiconductor device according to any one of Technical proposals 1-16, further comprising:
a first conductive part electrically connected to the second electrode,
a first conductive part position of at least a part of the first conductive part in the first direction is between a first electrode position of the first electrode in the first direction and a third electrode position of the third electrode in the first direction, and
a part of the first insulating member is between the first conductive part and the semiconductor member, and between the first conductive part and the third electrode.

### Technical Proposal 18

The semiconductor device according to Technical proposal 17, wherein
the first conductive part is located between the first partial region and the third electrode in the first direction.

### Technical Proposal 19

The semiconductor device according to Technical proposal 17, wherein
the third electrode further includes a third other electrode extending along the third electrode,
in the second direction, the third electrode is located between the third other electrode and the first conductive member, and
a part of the first insulating member is between the third other electrode and the third electrode.

### Technical Proposal 20

The semiconductor device according to Technical proposal 2, further comprising:
a fourth electrode electrically connected to the third electrode,
a direction from a part of the terminal region to the fourth electrode being along the first direction, and
a direction from the fourth electrode to the third electrode being along the second direction.

According to the embodiments, a semiconductor device is provided that can improve characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, conductive members, semiconductor members, semiconductor regions, conductive parts, and insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode, a direction from the first electrode to the second electrode being along a first direction:
a third electrode;
a first conductive member electrically connected to the second electrode, a second direction from the third electrode to at least a part of the first conductive member crossing the first direction, the first conductive member extending along a third direction crossing a plane including the first direction and the second direction, the first conductive member including a first conductive portion and a second conductive portion, a direction from the first conductive portion to the second conductive portion being along the third direction, the first conductive portion including a first conductive region, the second conductive portion including a second conductive region, a first material of the first conductive region being different from a second material of the second conductive region;
a semiconductor member provided between the first electrode and the second electrode, the semiconductor member including a first semiconductor layer of a first conductivity type and a second semiconductor layer of the first conductivity type, the first semiconductor layer including a first partial region and a second partial region, the first partial region being between the first electrode and the third electrode in the first direction, the second partial region being between the first electrode and the first conductive member in the first direction, the second partial region including a first semiconductor region and a second semiconductor region, the first semiconductor region being in contact with the first conductive region, the second semiconductor region being in contact with the second conductive region, at least a part of the second semiconductor layer being between the third electrode and the first conductive portion in the second direction, the second semiconductor layer being not provided between the third electrode and the second conductive portion in the second direction, a second impurity concentration of the first conductivity type in the second semiconductor layer being higher than a first impurity concentration of the first conductivity type in the first semiconductor layer; and
a first insulating member provided between the third electrode and the semiconductor member.

2. The semiconductor device according to claim 1, wherein
the semiconductor member includes a cell region, a terminal region, and an outer edge,
the terminal region is between the cell region and the outer edge in a direction crossing the first direction,
the first semiconductor region is included in the cell region, and
the second semiconductor region is included in the terminal region.

3. The semiconductor device according to claim 1, wherein
the second conductive region includes a first element including at least one selected from the group consisting of B, In, Ga, and Al,
the first conductive region does not include the first element, or a second concentration of the first element in the second conductive region is higher than a first concentration of the first element in the first conductive region.

4. The semiconductor device according to claim 1, wherein
the second conductive region includes oxygen, and
the first conductive region does not include oxygen, or a second oxygen concentration in the second conductive region is higher than a first oxygen concentration in the first conductive region.

5. The semiconductor device according to claim 1, wherein
a second barrier height of the second material is higher than a first barrier height of the first material.

6. The semiconductor device according to claim 1, wherein
the first conductive region forms a Schottky junction with the first semiconductor region.

7. The semiconductor device according to claim 1, wherein
the semiconductor member includes silicon.

8. The semiconductor device according to claim 1, wherein
the second conductive portion further includes a second intermediate region,
the second conductive region is between the semiconductor member and the second intermediate region, and
a second intermediate region material of the second intermediate region is different from the second material.

9. The semiconductor device according to claim 8, wherein
the first conductive portion and the second intermediate region satisfy a first condition, a second condition, or a third condition,
in the first condition, the first conductive portion includes W and the second intermediate region includes at least one selected from the group consisting of Pt and Ir,
in the second condition, the first conductive portion includes Ni and the second intermediate region includes at least one selected from the group consisting of Pt and Ir, and
in the third condition, the first conductive portion includes Pt and the second intermediate region includes Ir.

10. The semiconductor device according to claim 8, wherein
the second conductive region includes a first portion,
the first portion is between the second semiconductor region and the second intermediate region in the first direction, and
a first thickness of the first portion in the first direction is not less than 1 nm and not more than 50 nm.

11. The semiconductor device according to claim 8, wherein
the first semiconductor layer further includes a third partial region,
the third partial region includes a second side region,
at least a part of the second side region is between at least a part of the third electrode and the second conductive portion in the second direction,
the second conductive region includes a second portion, and
the second portion is between the second side region and the second intermediate region in the second direction.

12. The semiconductor device according claim 11, wherein
a second thickness of the second portion in the second direction is not less than 1 nm and not more than 50 nm.

13. The semiconductor device according to claim 1, wherein
the first semiconductor layer further includes a third partial region,
the third partial region includes a first side region and a second side region,
at least a part of the first side region is between at least a part of the third electrode and the first conductive portion in the second direction, and
at least a part of the second side region is between at least a part of the third electrode and the second conductive portion in the second direction.

14. The semiconductor device according to claim 13, wherein
a first side region thickness of the first side region in the second direction is not less than 10 nm and not more than 200 nm.

15. The semiconductor device according to claim 1, wherein
a first length of the first conductive portion in the third direction is longer than a second length of the second conductive portion in the third direction.

16. The semiconductor device according to claim 1, wherein
the third electrode extends along the third direction.

17. The semiconductor device according to claim 1, further comprising:
a first conductive part electrically connected to the second electrode,
a first conductive part position of at least a part of the first conductive part in the first direction is between a first electrode position of the first electrode in the first direction and a third electrode position of the third electrode in the first direction, and
a part of the first insulating member is between the first conductive part and the semiconductor member, and between the first conductive part and the third electrode.

18. The semiconductor device according to claim 17, wherein
the first conductive part is located between the first partial region and the third electrode in the first direction.

19. The semiconductor device according to claim 17, wherein
the third electrode further includes a third other electrode extending along the third electrode,
in the second direction, the third electrode is located between the third other electrode and the first conductive member, and
a part of the first insulating member is between the third other electrode and the third electrode.

20. The semiconductor device according to claim 2, further comprising:
a fourth electrode electrically connected to the third electrode,
a direction from a part of the terminal region to the fourth electrode being along the first direction, and
a direction from the fourth electrode to the third electrode being along the second direction.
